(19) United States
(12) Patent Application Publication
(10) Pub. No.: US 2014/0253892 A1
(43) Pub. Date: Sep. 11, 2014

(54) Extreme Ultraviolet Lithography Projection Optics System and Associated Methods

(71) Applicant: Taiwan Semiconductor Manufacturing Company, Ltd., Hsin-Chu (TW)

(72) Inventors: Shinn-Sheng Yu, Hsinchu (TW); Yen-Cheng Lu, New Taipei City (TW); Anthony Yen, Hsinchu County (TW)

(73) Assignee: Taiwan Semiconductor Manufacturing Company, Ltd., Hsin-Chu (TW)

(21) Appl. No.: 14/203,348

(22) Filed: Mar. 10, 2014

Related U.S. Application Data
(60) Provisional application No. 61/776,356, filed on Mar. 11, 2013.

(51) Int. Cl. G03F 7/20; G02B 17/06

(52) U.S. Cl. CPC G03F 7/70233; G02B 17/0647
USPC 355/66

(57) ABSTRACT

The present disclosure provides an extreme ultraviolet lithography system. The extreme ultraviolet lithography system includes a projection optics system to image a pattern of a mask on a wafer. The projection optics system includes between two to five mirrors. The two to five mirrors are designed and configured to have a numerical aperture less than about 0.50, an image field size at the wafer hat is greater than or equal to about 20 mm, and a pupil plane that includes central obscuration. In an example, the central obscuration has a radius that is less than or equal to 50% of a radius of the pupil plane. In an example, the central obscuration has an area that is less than or equal to 25% of an area of the pupil plane.

### BACKGROUND

This patent claims the benefit of U.S. Ser. No. 61/776,356 filed Mar. 11, 2013, which is hereby incorporated by reference.

The semiconductor integrated circuit (IC) industry has experienced rapid growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed. For example, extreme ultraviolet (EUV) lithography systems have been implemented to perform higher resolution lithography processes. EUV lithography systems (scanners) employ radiation sources that generate light in the EUV region. Some EUV scanners can provide 4× reduction projection printing, similar to some optical scanners, except that the EUV scanners use reflective rather than refractive optics (for example, mirrors instead of lenses). A projection optics system of the EUV lithography system typically images EUV radiation reflected from a mask onto a wafer. Because reflectivity of the mirrors in the projection optics system is limited, a source power of the EUV source that generates the EUV radiation is higher than desirable to ensure sufficient throughput, and a number of mirrors required for the resolution requirements is higher than desired. Accordingly, although existing EUV lithography systems have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a schematic diagram of an extreme ultraviolet (EUV) lithography system for imaging a pattern of a mask onto a wafer according to various aspects of the present disclosure.

FIG. 2 is a schematic diagram of a projection optics module that can be included in the EUV lithography system of FIG. 1 according to various aspects of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

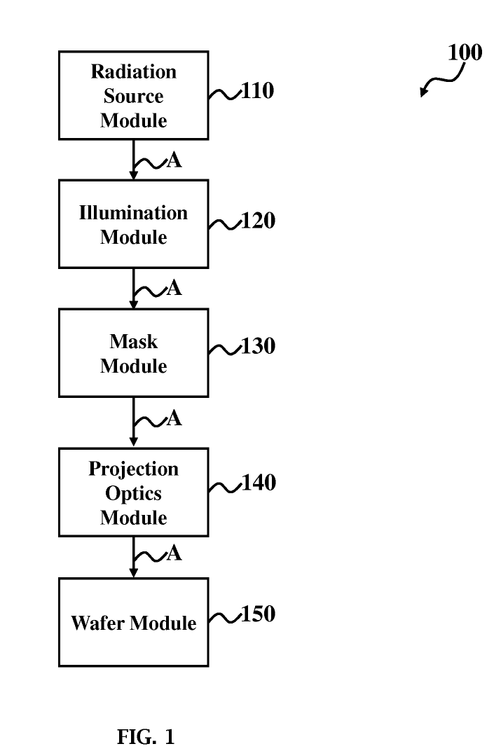

FIG. 1 is a schematic diagram of an extreme ultraviolet (EUV) lithography system 100 for imaging a pattern of a mask onto a wafer according to various aspects of the present disclosure. In the depicted embodiment, the EUV lithography system 100 includes a radiation source module 110, an illumination module 120, a mask module 130 that includes the mask, a projection optics module 140, and a wafer module 150 that includes the wafer. The EUV lithography system 100 is designed to operate in a step-and-scan mode. FIG. 1 has been simplified for the sake of clarity to better understand the inventive concepts of the present disclosure. Additional features can be added in the EUV lithography system 100, and some of the features described below can be replaced or eliminated for additional embodiments of the EUV lithography system 100.

The radiation source module 110 includes a radiation source that generates and emits radiation (light) A. In the depicted embodiment, the radiation source emits electromagnetic radiation having a wavelength in the EUV range, for example, from about 1 nm to about 100 nm. In an example, the radiation source emits EUV radiation having a wavelength of about 13.5 nm. In an example, the radiation source is an optical source that generates ultraviolet (UV) radiation, deep UV (DUV) radiation, EUV radiation, x-ray radiation, vacuum ultraviolet (VUV) or a combination thereof. Alternatively, the radiation source is another light source designed to generate and emit radiation having a wavelength less than about 100 nm.

The illumination module 120 collects, guides, and directs the light A, such that light A is projected onto the mask of the mask module 130. The illumination module 120 includes various optical components for collecting, directing, and shaping the light A onto the mask. Such optical components include refractive components, reflective components, magnetic components, electromagnetic components, electrostatic components, other types of components for collecting, directing, and shaping the light A, or combinations thereof. For example, the illumination module 120 may include various condensers, lenses, mirrors, zone plates, apertures, shadow masks, and/or other optical components designed to collect, guide, and direct the light A from the radiation source module 110 onto the mask.

The mask module 130 includes a mask stage for holding the mask and manipulating a position of the mask. The mask includes a mask pattern that corresponds with a pattern of an integrated circuit device. In the present example, the mask is a reflective mask, such as a phase shift mask. The phase shift mask may be an attenuated phase shift mask (AttPSM) or an alternating phase shift mask (AltPSM). In an example, where the mask is a phase shift mask, the mask includes absorptive regions, which absorb light incident thereon, and reflective regions, which reflect light incident thereon. The absorptive regions can be configured to reflect light incident thereon with a phase different than light reflected by the reflective regions, such that resolution and image quality of the pattern transferred to the wafer can be enhanced. The reflective and absorptive regions of the mask are patterned such that light reflected from the reflective regions (and, in some cases, the absorptive regions) projects a mask pattern image of the mask pattern to the projection optics module 140 (and ultimately to the wafer at the wafer module 150). For example, during a lithography patterning process, the light A is projected onto the mask of the mask module 130 via the illumination module 120, and a portion of the light A is reflected from the mask to the projection optics module 140.

The projection optics module 140 collects, guides, and directs the light A reflected from the mask of the mask module 130 to the wafer of the wafer module 150. The projection optics module 140 focuses the reflected light A to form an image of the mask pattern on the wafer. In the present example, the projection optics module 140 has a magnification that is less than one, thereby reducing a size of the mask pattern image of the reflected light A collected from the mask module 130. The projection optics module 140 includes various optical components for collecting, directing, and shaping the reflected light A onto the wafer. Such optical components include refractive components, reflective components, magnetic components, electromagnetic components, electrostatic components, other types of components for collecting, directing, and shaping the light A, or combinations thereof. In an example, the projection optics module uses Schwarzschild optics.

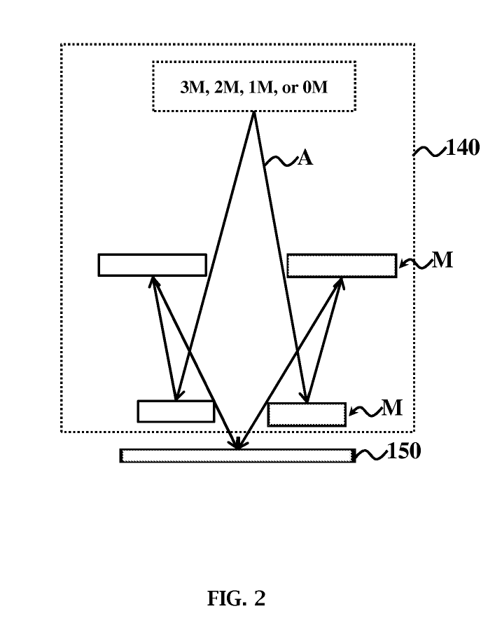

FIG. 2 is a schematic diagram of the projection optics module 140 according to various aspects of the present disclosure. The projection optics module 140 includes less than six mirrors (designated by “M” in FIG. 2) (for example, five, four, three, or two mirrors) configured to collect, guide, and direct the light A reflected from the mask of the mask module 130 to the wafer of the wafer module 150. The five, four, three, or two mirrors are designed and configured so that the projection optics module 140 has a numerical aperture that is less than about 0.50. In an example, the numerical aperture of the projection optics module 140 is greater than or equal to 0.35 and less than about 0.50. The five, four, three, or two mirrors are further designed and configured so that an image field size of the light A imaged at the wafer by the projection optics module 140 is greater than or equal to about 20 mm. In the depicted embodiment, the last two mirrors (M) include central obscuration, such that a pupil plane of the projection optics module 140 has a central obscuration. In an example, the shape of the pupil plane is disk-like. In an example, the central obscuration has a radius that is less than or equal to 50% of a radius of the pupil plane. In an example, the central obscuration has an area that is less than or equal to 25% of an area of the pupil plane. It is noted that, in FIG. 2, the configuration of the mirrors of the projection optics module 140 is merely exemplary, and any configuration of the mirrors of the projection optics module 140 that accomplishes the described numerical aperture, image field size, and central obscuration characteristics is contemplated by the present disclosure. It is further noted that FIG. 2 has been simplified for the sake of clarity to better understand the inventive concepts of the present disclosure. For example, the projection optics module 140 may include not illustrated refractive components, reflective components, magnetic components, electromagnetic components, electrostatic components, other types of components for collecting, directing, and shaping the light A, or combinations thereof.

The wafer module 150 includes a wafer stage for holding the wafer and manipulating a position of the wafer. The wafer includes a resist layer disposed over a substrate. The resist layer is sensitive to EUV radiation. The mask pattern of the mask may be imaged onto the wafer in a repetitive fashion, although other patterning schemes are contemplated by the present disclosure.

The present disclosure provides for many different embodiments. An exemplary EUV lithography system has a projection optics system that includes less than six mirrors configured and designed to image a pattern of a mask on a wafer. The projection optics system is further configured and designed to achieve a numerical aperture less than about 0.50, an image field size of radiation imaged at the wafer that is greater than or equal to about 20 mm, and a pupil plane that includes central obscuration. In an example, the central obscuration has a radius that is less than or equal to 50% of a radius of the pupil plane. In an example, the central obscuration has an area that is less than or equal to 25% of an area of the pupil plane. Such projection optics system facilitates reduction in a power of the radiation source. In an example, the numerical aperture is greater than or equal to 0.35. In an example, the projection optics system includes at least two mirrors, where the at least two mirrors include central obscuration. The projection optics system may achieve such numerical aperture, image field size, and central obscuration using Schwarzchild optics.

In another example, an EUV lithography system includes a radiation source module; an illumination module; a mask module that includes a mask; a projection optics module; and a wafer module that includes a wafer. The radiation source module emits EUV radiation that the illumination module collects and directs to the mask, the mask reflects a portion of the EUV radiation to the projection optics module, and the projection optics module collects and directs the reflected portion of the EUV radiation to the wafer. The projection optics module includes between two to five mirrors, where the two to five mirrors are designed and configured to have a numerical aperture less than about 0.50, provide an image field size of the reflected portion of the EUV radiation imaged at the wafer that is greater than or equal to about 20 mm, and have a pupil plane that includes central obscuration. In an example, the central obscuration has a radius that is less than or equal to 50% of a radius of the pupil plane. In an example, the central obscuration has an area that is less than or equal to 25% of an area of the pupil plane. In an example, the numerical aperture is greater than or equal to 0.35. The projection optics module may include Schwarzchild optics.

In yet another example, an EUV lithography method provides a projection optics system that has between two to five mirrors, wherein the two to five mirrors are designed and configured to have a numerical aperture less than about 0.50, provide an image field size of EUV radiation imaged at a wafer that is greater than or equal to about 20 mm, and have a pupil plane that includes central obscuration; illuminates a mask with EUV radiation; and collects, by the projection optics system, EUV radiation reflected from the mask, where the collected EUV radiation is reflected from the two to five mirrors before being imaged on the wafer by the projection optics system. The EUV radiation has a wavelength of about 1 nm to about 100 nm. In an example, the collected EUV radiation travels through a central obscuration of at least two mirrors before being imaged on the wafer. In an example, the numerical aperture is also greater than or equal to about 0.35.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An extreme ultraviolet (EUV) lithography system comprising:
a projection optics system that includes less than six mirrors configured and designed to image a pattern of a mask on a wafer, and the projection optics system further configured and designed to achieve:
a numerical aperture less than about 0.50;
an image field size of radiation imaged at the wafer that is greater than or equal to about 20 mm; and
a pupil plane that includes central obscuration.

2. The EUV lithography system of claim 1 wherein the numerical aperture is greater than or equal to 0.35.

3. The EUV lithography system of claim 1 wherein the projection optics system includes at least two mirrors.

4. The EUV lithography system of claim 3 wherein the at least two mirrors include central obscuration.

5. The EUV lithography system of claim 1 the central obscuration has a radius that is less than or equal to 50% of a radius of the pupil plane.

6. The EUV lithography system of claim 1 the central obscuration has an area that is less than or equal to 25% of an area of the pupil plane.

7. The EUV lithography system of claim 1 wherein the projection optics system includes Schwarzchild optics.

8. The EUV lithography system of claim 1 wherein the radiation imaged at the wafer has a wavelength of about 1 nm to about 100 nm.

9. The EUV lithography system of claim 1 wherein the radiation imaged at the wafer has a wavelength of about 13.5 nm.

10. The EUV lithography system of claim 1 wherein the mask is a reflective mask.

11. An extreme ultraviolet (EUV) lithography system comprising:
a radiation source module;
an illumination module;
a mask module that includes a mask;
a projection optics module;
a wafer module that includes a wafer;
wherein the radiation source module emits EUV radiation that the illumination module collects and directs to the mask, the mask reflects a portion of the EUV radiation to the projection optics module, and the projection optics module collects and directs the reflected portion of the EUV radiation to the wafer; and
further wherein the projection optics module includes between two to five mirrors, wherein the two to five mirrors are designed and configured to have a numerical aperture less than about 0.50, provide an image field size of the reflected portion of the EUV radiation imaged at the wafer that is greater than or equal to about 20 mm, and have a pupil plane that includes central obscuration.

12. The EUV lithography system of claim 11 wherein the central obscuration has a radius that is less than or equal to 50% of a radius of the pupil plane.

13. The EUV lithography system of claim 11 wherein the central obscuration has an area that is less than or equal to 25% of an area of the pupil plane.

14. The EUV lithography system of claim 11 wherein the numerical aperture is greater than or equal to about 0.35.

15. The EUV lithography system of claim 11 wherein the projection optics module includes Schwarzchild optics.

16. The EUV lithography system of claim 11 wherein the EUV radiation has a wavelength of about 13.5 nm.

17. An extreme ultraviolet (EUV) lithography method comprising:
providing a projection optics system that has between two to five mirrors, wherein the two to five mirrors are designed and configured to have a numerical aperture less than about 0.50, provide an image field size of EUV radiation imaged at a wafer that is greater than or equal to about 20 mm, and have a pupil plane that includes central obscuration;
illuminating a mask with EUV radiation; and
collecting, by the projection optics system, EUV radiation reflected from the mask, wherein the collected EUV radiation is reflected from the two to five mirrors before being imaged on the wafer by the projection optics system.

18. The EUV lithography method of claim 17 wherein the EUV radiation has a wavelength of about 1 nm to about 100 nm.

19. The EUV lithography method of claim 17 wherein the collected EUV radiation travels through a central obscuration of at least two mirrors before being imaged on the wafer.

20. The EUV lithography method of claim 17 wherein the numerical aperture is greater than or equal to about 0.35.
